(19) United States
(12) Patent Application Publication
(10) Pub. No.: US 2013/0063877 A1
(43) Pub. Date: Mar. 14, 2013

(54) Protective Coverings and Methods of Making and Using the Same

(71) Applicant: Russell F. Still, Cumming, GA (US)

(72) Inventor: Russell F. Still, Cumming, GA (US)

(21) Appl. No.: 13/594,921

(22) Filed: Aug. 27, 2012

Related U.S. Application Data
(60) Provisional application No. 61/533,468, filed on Sep. 12, 2011.

(51) Int. Cl. H05K 5/03; H05K 7/20; H05K 7/02; H05K 5/00

(52) U.S. Cl. 361/679.01; 312/223.1; 312/223.6

(57) ABSTRACT

Protective coverings suitable for protecting and housing electronic devices such as an APPLE™ iPAD™ tablet are disclosed. Methods of making and using protective coverings are also disclosed.

### CROSS-REFERENCE TO RELATED APPLICATIONS

This patent application claims the benefit of priority to U.S. provisional patent application Ser. No. 61/533,468 entitled “PROTECTIVE COVERINGS AND METHODS OF MAKING AND USING THE SAME” filed on Sep. 12, 2011, the subject matter of which is incorporated herein in its entirety.

### FIELD OF THE INVENTION

The present invention relates generally to protective coverings suitable for protecting and housing electronic devices such as an APPLE™ iPad™ tablet computer. The present invention further relates to methods of making and using protective coverings suitable for protecting and housing electronic devices.

### BACKGROUND OF THE INVENTION

Numerous products exist that act as a protective stand and/or a carrying case for a class of flat electronic/computer devices such as an APPLE™ iPad™ tablet computer. However, known devices lack one or more desirable features. For example, known devices typically allow only a narrow range of positioning configurations in three-dimensional space for the electronic device they support. Because of this, a person using such a product will be limited to the number of body positions he/she may comfortably assume while using known devices.

### SUMMARY OF THE INVENTION

The present invention provides protective devices (also referred to herein as “protective coverings”) for protecting and securing an electronic/computer device such as an APPLE™ iPad™ tablet computer during use and storage. In one exemplary embodiment of the present invention, the protective device of the present invention typically comprises at least two basic parts: a base component referred to herein as “the housing component,” and a retractable stand referred to herein as “the fold-out prop.”

In another exemplary embodiment of the present invention, the protective covering comprises a protective covering for protecting and housing an electronic device, wherein the protective covering comprises a housing component comprising an inner housing front surface; at least one housing side wall extending upward from the inner housing front surface and comprising an outer housing side wall surface, an inner housing side wall surface opposite the outer housing side wall surface, and an upper side wall surface between the inner housing side wall surface and the outer housing side wall surface; at least one housing connection member along the inner housing side wall surface and extending over the inner housing front surface; an outer housing front surface; an intermediate housing side wall extending upward from the inner housing front surface and separating the inner housing front surface from the outer housing front surface; a rear housing surface opposite the inner housing front surface and the outer housing front surface; and an outer peripheral edge extending completely around the housing component; the inner housing front surface and the at least one housing side wall being sized and dimensioned so as to (i) receive and surround an electronic device positionable along the inner housing front surface, and (ii) secure the electronic device within the protective covering via the at least one housing connection member.

In yet another exemplary embodiment of the present invention, the protective covering comprises a protective covering for protecting and housing an electronic device, wherein the protective covering comprises: (I) a housing component comprising an inner housing front surface; at least one housing side wall extending upward from the inner housing front surface and comprising an outer housing side wall surface, an inner housing side wall surface opposite the outer housing side wall surface, and an upper side wall surface between the inner housing side wall surface and the outer housing side wall surface; at least one housing connection member along the inner housing side wall surface and extending over the inner housing front surface; an outer housing front surface; an intermediate housing side wall extending upward from the inner housing front surface and separating the inner housing front surface from the outer housing front surface; a rear housing surface opposite the inner housing front surface and the outer housing front surface; and an outer peripheral edge extending completely around the housing component; the inner housing front surface and the at least one housing side wall being sized and dimensioned so as to (i) receive and surround an electronic device positionable along the inner housing front surface, and (ii) secure the electronic device within the protective covering via the at least one housing connection member; and (II) a fold-out prop member comprising a connected fold-out prop member end, and a moveable fold-out prop member end opposite the connected fold-out prop member end, the connected fold-out prop member end being connected to the rear housing surface so that the moveable fold-out prop member end is operatively adapted to move from a first parallel position, wherein the moveable fold-out prop member end extends along and is proximate to the rear housing surface, to a second angled position, wherein the moveable fold-out prop member end is positioned away from the rear housing surface; wherein the housing component further comprises a recessed groove extending along the rear housing surface, and the fold-out prop member is sized so as to fit within the recessed groove when the fold-out prop member is in the first parallel position.

In yet a further exemplary embodiment of the present invention, the protective covering comprises a protective covering for protecting and housing an electronic device, wherein the protective covering comprises: (I) a housing component comprising an inner housing front surface; at least one housing side wall extending upward from the inner housing front surface and comprising an outer housing side wall surface, an inner housing side wall surface opposite the outer housing side wall surface, and an upper side wall surface between the inner housing side wall surface and the outer housing side wall surface; at least one housing connection member along the inner housing side wall surface and extending over the inner housing front surface; an outer housing front surface; an intermediate housing side wall extending upward from the inner housing front surface and separating the inner housing front surface from the outer housing front surface; a rear housing surface opposite the inner housing front surface and the outer housing front surface; an outer peripheral edge extending completely around the housing component; a gripping aperture extending through the housing component from the outer housing front surface to the rear housing surface, the gripping aperture being sized and dimensioned so as to enable a user to grab the protective covering by extending at least a portion of a hand through the gripping aperture; one or more air vent apertures extending through the housing component from the inner housing front surface to the rear housing surface, the one or more air vent apertures being sized and dimensioned so as to provide unobstructed air flow from an electronic device positioned along the inner housing front surface; a recessed groove extending along the rear housing surface; and a rectangular shape; wherein the at least one housing side wall and the intermediate housing side wall together represent four housing side walls, and each of three of the four housing side walls independently comprises at least one opening or recessed area therein, each of the at least one opening or recessed area (i) extending from the outer housing side wall surface to the inner housing front surface, and being sized to enable one or more electrical cords, cables, or both to connect to an electronic device positioned along the inner housing front surface of the housing component; the inner housing front surface and the at least one housing side wall being sized and dimensioned so as to (i) receive and surround an electronic device positionable along the inner housing front surface, and (ii) secure the electronic device within the protective covering via the at least one housing connection member; and (II) a fold-out prop member comprising a connected fold-out prop member end, and a moveable fold-out prop member end opposite the connected fold-out prop member end, the connected fold-out prop member end being connected to the rear housing surface so that the moveable fold-out prop member end is operatively adapted to move from a first parallel position, wherein the moveable fold-out prop member end extends along and is proximate to the rear housing surface and positioned within the recessed groove, to a second angled position, wherein the moveable fold-out prop member end is positioned away from the rear housing surface.

The present invention is also directed to methods of making protective coverings. In one exemplary embodiment of the present invention, the method of making a protective covering comprises the step of forming at least one molded part comprising a housing component, wherein the housing component comprises an inner housing front surface; at least one housing side wall extending upward from the inner housing front surface and comprising an outer housing side wall surface, an inner housing side wall surface opposite the outer housing side wall surface, and an upper side wall surface between the inner housing side wall surface and the outer housing side wall surface; at least one housing connection member along the inner housing side wall surface and extending over the inner housing front surface; an outer housing front surface; an intermediate housing side wall extending upward from the inner housing front surface and separating the inner housing front surface from the outer housing front surface; a rear housing surface opposite the inner housing front surface and the outer housing front surface; and an outer peripheral edge extending completely around the housing component; the inner housing front surface and the at least one housing side wall being sized and dimensioned so as to (i) receive and surround an electronic device positionable along the inner housing front surface, and (ii) secure the electronic device within the protective covering via the at least one housing connection member.

The herein disclosed methods of making a protective covering may further comprise one or more additional steps including, but not limited to, forming a fold-out prop member comprising a connected fold-out prop member end, and a moveable fold-out prop member end opposite the connected fold-out prop member end, the connected fold-out prop member end being connectable to a rear housing surface of a housing component so that the moveable fold-out prop member end is operatively adapted to move from a first parallel position, wherein the moveable fold-out prop member end extends along and is proximate to the rear housing surface, to a second angled position, wherein the moveable fold-out prop member end is positioned away from the rear housing surface; forming a housing component that further comprises a recessed groove extending along a rear housing surface of the housing component, with the recessed groove and fold-out prop member being sized so that the fold-out prop member fits within the recessed groove when the fold-out prop member is in the first parallel position; printing and/or adhering an image onto an outer surface of the at least one molded part; and packaging the protective covering.

The present invention is further directed to methods of using a protective covering to protect and house an electronic device. In one exemplary embodiment of the present invention, the method of using a protective covering comprises a method of covering at least a portion of an electronic device, wherein the method comprises positioning and securing the electronic device along an inner surface of a housing component.

In another exemplary embodiment, the method of using a protective covering comprises withdrawing a fold-out prop member from a first position adjacent a lower surface of the housing component; and adjusting a height of the electronic device by adjusting a position of the fold-out prop member relative to the housing component.

These and other features and advantages of the present invention will become apparent after a review of the following detailed description of the disclosed embodiments and the appended claims.

### BRIEF DESCRIPTION OF THE FIGURES

The present invention is further described with reference to the appended figures, wherein:

FIG. 1 depicts a perspective view of an exemplary protective covering of the present invention in combination with an iPad™ positioned within the protective covering;

FIG. 2 depicts a perspective view of another exemplary protective covering of the present invention in combination with an iPad™ positioned within the protective covering;

FIG. 3 depicts a perspective view of the exemplary protective covering shown in FIG. 2 without the iPad™;

FIG. 4 depicts a rear view of the exemplary protective covering shown in FIG. 3;

FIG. 5 depicts a cross-sectional view of the exemplary protective covering shown in FIG. 3 as viewed along line A-A;

FIG. 6 depicts a cross-sectional view of the exemplary protective covering shown in FIG. 3 as viewed along line B-B;

FIG. 7 is a photograph of the exemplary protective covering shown in FIG. 2 (note, this photograph is included to clearly show features of the exemplary protective covering shown in FIG. 2 given the poor quality of informal FIG. 2);

FIG. 8 is a photograph of the exemplary protective covering shown in FIG. 3 (note, this photograph is included to clearly show features of the exemplary protective covering shown in FIG. 3 given the poor quality of informal FIG. 3); and

FIG. 9 is a photograph of the exemplary protective covering shown in FIG. 4 (note, this photograph is included to clearly show features of the exemplary protective covering shown in FIG. 4 given the poor quality of informal FIG. 4).

### DETAILED DESCRIPTION OF THE INVENTION

The present invention is directed to protective coverings suitable for protecting and housing electronic devices such as an APPLE™ iPAD™ tablet. The present invention is further directed to methods of making, as well as methods of using protective coverings suitable for protecting and housing electronic devices.

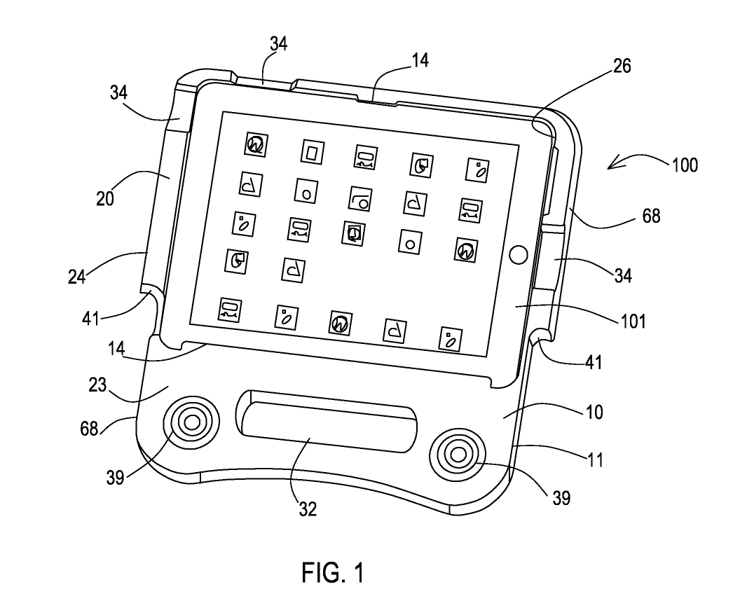

FIG. 1 depicts a perspective view of an exemplary protective covering/electronic device combination 100 of the present invention. As shown in FIG. 1, exemplary protective covering/electronic device combination 100 comprises exemplary protective covering 10 and exemplary electronic device 101 (e.g., an APPLE™ iPAD™ tablet). Although throughout the present disclosure an APPLE™ iPAD™ tablet is used to exemplify exemplary electronic device 101, other electronic devices may be used in place of the disclosed APPLE™ iPAD™ tablet.

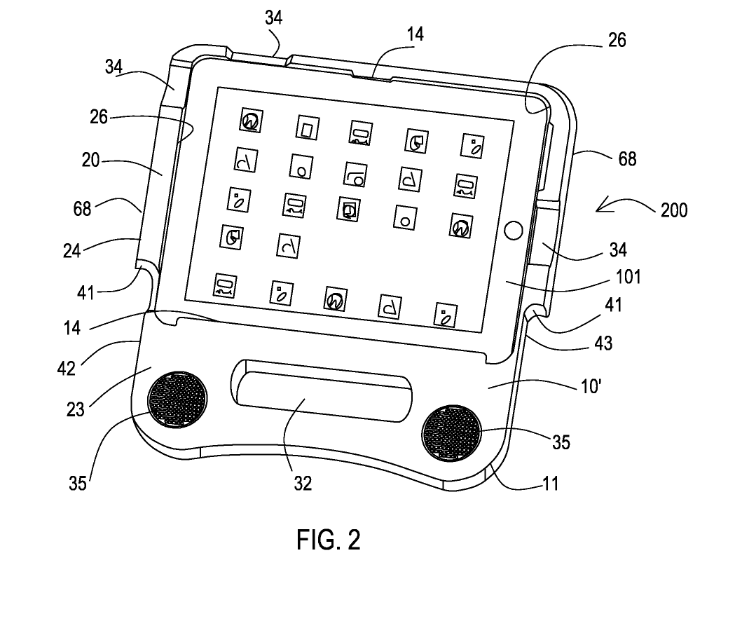

FIG. 2 depicts a perspective view of another exemplary protective covering/electronic device combination 200 of the present invention. As shown in FIG. 2, exemplary protective covering/electronic device combination 200 comprises exemplary protective covering 10′ and exemplary electronic device 101 (e.g., an APPLE™ iPAD™ tablet).

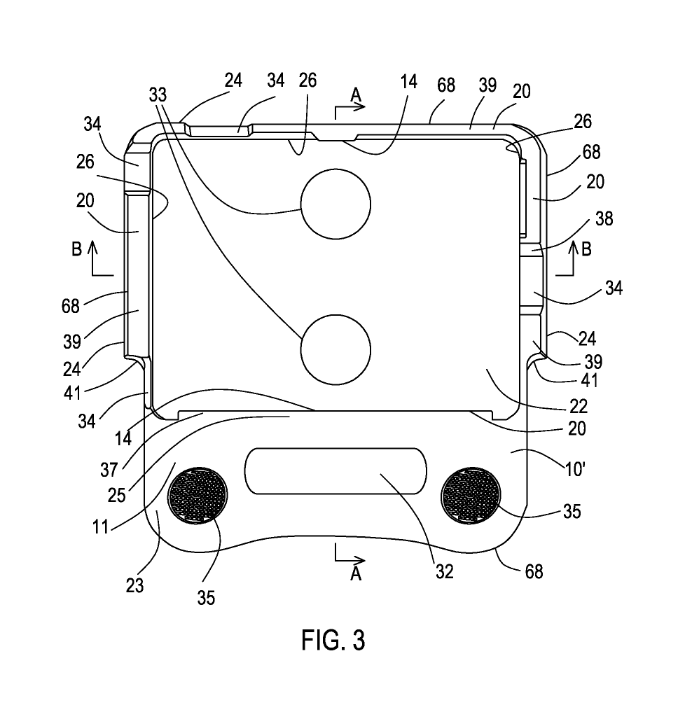

FIG. 3 depicts a perspective view of exemplary protective covering 10′ shown in FIG. 2 without exemplary electronic device 101 positioned therein. As shown in FIG. 3, exemplary protective covering 10′ of the present invention comprises exemplary housing component 11. Exemplary housing component 11 comprises an inner housing front surface 22; at least one housing side wall 20 extending upward from inner housing front surface 22 and comprising an outer housing side wall surface 24, an inner housing side wall surface 26 opposite outer housing side wall surface 24, and an upper side wall surface 39 between inner housing side wall surface 26 and outer housing side wall surface 24; at least one housing connection member 14 along inner housing side wall surface 26 and extending over inner housing front surface 22; an outer housing front surface 23; an intermediate housing side wall 25 extending upward from inner housing front surface 22 and separating inner housing front surface 22 from outer housing front surface 23; a rear housing surface 16 opposite inner housing front surface 22 and outer housing front surface 23; and an outer peripheral edge 68 extending completely around housing component 11.

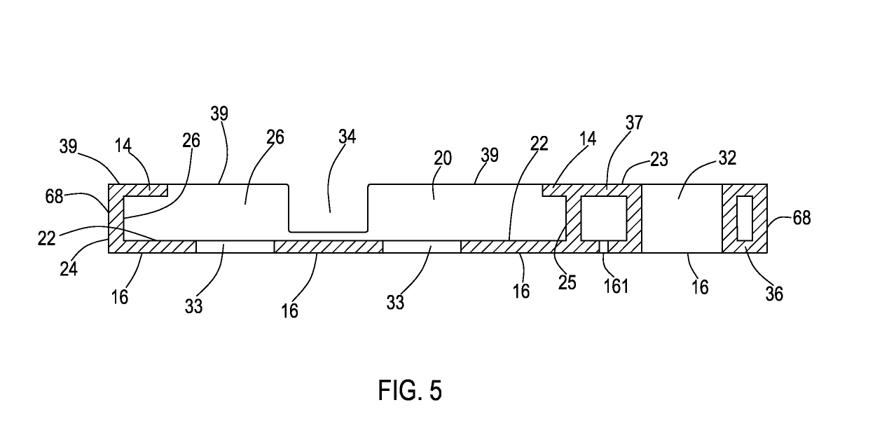

As shown in FIG. 3, inner housing front surface 22 and the at least one housing side wall 20 (i.e., three edge side walls 20 are shown along with intermediate side wall 25) are sized and dimensioned so as to (i) receive and surround an electronic device (e.g., electronic device 101 shown in FIGS. 1-2) positionable along inner housing front surface 22, and (ii) secure the electronic device within protective covering 10′ via at least one housing connection member 14 (e.g., such as housing connection members 14 shown in FIGS. 3 and 5).

As further shown in FIG. 3, protective covering 10′ further comprises a gripping aperture 32 extending through housing component 11 from outer housing front surface 23 to rear housing surface 16 (see, FIG. 5) with gripping aperture 32 being sized and dimensioned so as to enable a user (not shown) to grab protective covering 10′ by extending at least a portion of a hand (e.g., one or more fingers and optionally the palm of the hand) through gripping aperture 32.

Exemplary protective covering 10′ may further comprises one or more air vent apertures such as exemplary air vent apertures 33 extending through housing component 11 from inner housing front surface 22 to rear housing surface 16. Each of one or more air vent apertures 33 are sized and dimensioned so as to provide unobstructed air flow from an electronic device (e.g., electronic device 101 shown in FIGS. 1-2) positioned along inner housing front surface 22.

As shown in FIGS. 1-3 and 5, protective coverings of the present invention may further comprise a housing component such as exemplary housing component 11, wherein the housing component further comprises at least one opening or recessed area 34 within at least one housing side wall 20 and extending from outer housing side wall surface 24 to inner housing front surface 26, wherein each opening or recessed area is independently sized to enable one or more electrical cords, cables, or both (not shown) to connect to an electronic device (e.g., electronic device 101 shown in FIGS. 1-2) positioned along inner housing front surface 22 of housing component 11.

Typically, housing component 11 has a rectangular shape as shown in FIGS. 1-4; however, it should be understood that the overall shape of housing component 11 is not limited in any way. As shown in FIGS. 1-4, in dome desired embodiments, housing component 11 comprises housing side walls comprising (i) three housing side walls 20 and (ii) intermediate housing side wall housing component 25, which together represent four inner housing side walls, and each of three of the four housing side walls independently comprises at least one opening or recessed area 34 therein, and each of the opening(s) or recessed area(s) 34 are sized to enable one or more electrical cords, cables, or both (not shown) to be connected to an electronic device (e.g., electronic device 101 shown in FIGS. 1-2) positioned along inner housing front surface 22 of housing component 11.

As shown in FIGS. 2-3, in some embodiments, housing component 11 may further comprises at least one speaker outlet 35 positioned along outer housing front surface 23, wherein each speaker outlet 35 is sized and dimensioned to match a speaker front surface of a speaker (not shown) positionable within housing component 11 (i.e., within a hollow interior of housing component 11 between outer housing front surface 23 and rear housing surface 16).

In some embodiments, housing component 11 comprises two speaker outlets 35 positioned along outer housing front surface 23 on opposite sides of gripping aperture 32, wherein each speaker outlet 35 is sized and dimensioned to match a speaker front surface of a speaker (not shown) positionable within housing component 11.

In other embodiments, such as shown in FIG. 1, housing component 11 comprises one or more raised circular surface features 39 along outer housing front surface 23. As shown in FIG. 1, in some embodiments, housing component 11 comprises two raised circular surface features 39 positioned along outer housing front surface 23 on opposite sides of gripping aperture 32.

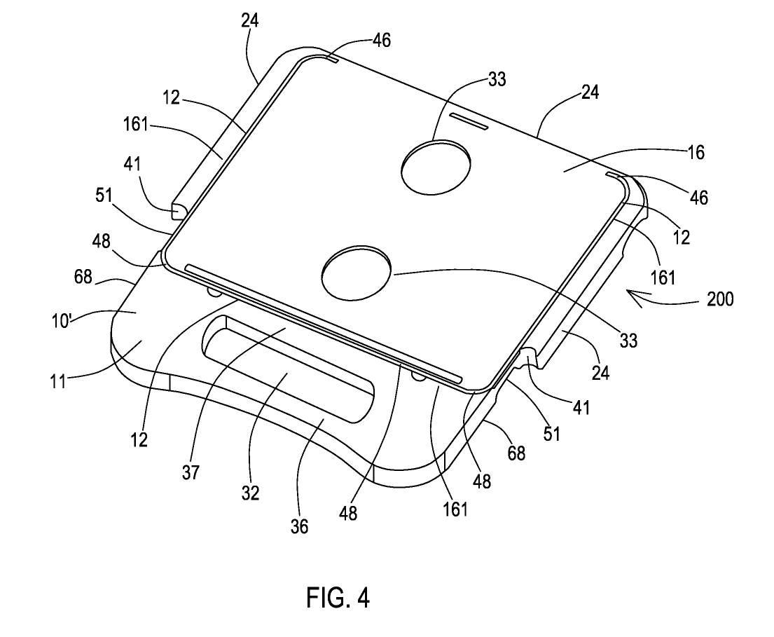

In some exemplary embodiments, housing component 11 further comprises a recessed groove 161 extending along rear housing surface 16 (see, FIG. 4). In these exemplary embodiments, a fold-out prop member, such as fold-out prop member 12, described below, is sized so as to fit within recessed groove 161 when the fold-out prop member is in a first parallel position (discussed below). Typically, recessed groove 161 extends within at least a portion of at least one housing side wall 20.

As discussed above and as shown in FIGS. 1-4, exemplary housing component 11 may have a rectangular shape, wherein at least one housing side wall 20 extends along at least two sides of the rectangular shape, and recessed groove 161 extends within the at least one housing side wall 20 along the at least two sides of the rectangular shape (see, FIG. 4).

FIG. 4 depicts a rear view of exemplary protective covering 10′ shown in FIG. 3. As shown in FIG. 4, the protective devices of the present invention may further comprise a fold-out prop member component such as exemplary support member 12. The fold-out prop member can be deployed for use, or retracted into recessed groove 161 within housing component 11 when not in use.

As shown in FIG. 4, exemplary fold-out prop member 12 comprises a connected fold-out prop member end 46, and a moveable fold-out prop member end 48 opposite connected fold-out prop member end 46. Connected fold-out prop member end 46 is connected to rear housing surface 16 (or a housing interior proximate to rear housing surface 16) so that moveable fold-out prop member end 48 is operatively adapted to move from a first parallel position, wherein moveable fold-out prop member end 48 extends along and is proximate to rear housing surface 16, to a second angled position, wherein moveable fold-out prop member end 48 is positioned away from rear housing surface 16.

Desirably, fold-out prop member 12 is operatively adapted to remain in a first parallel position or a second angled position unless a threshold amount of force is applied to fold-out prop member 12.

FIG. 5 depicts a cross-sectional view of exemplary protective covering 10′ shown in FIG. 3 as viewed along line A-A. FIG. 5 provides a view of many of the above-described components and features of exemplary housing component 11. Components and features shown in FIG. 5 include, but are not limited to, housing connection members 14 extending over inner housing front surface 22 from inner housing side wall surface 26 and intermediate side wall 25; two air vent apertures 33 positioned within and through inner housing front surface 22; opening or recessed area 34 within housing side wall 20; housing component members 36 and 37 on opposite sides of gripping aperture 32; and recessed groove 161.

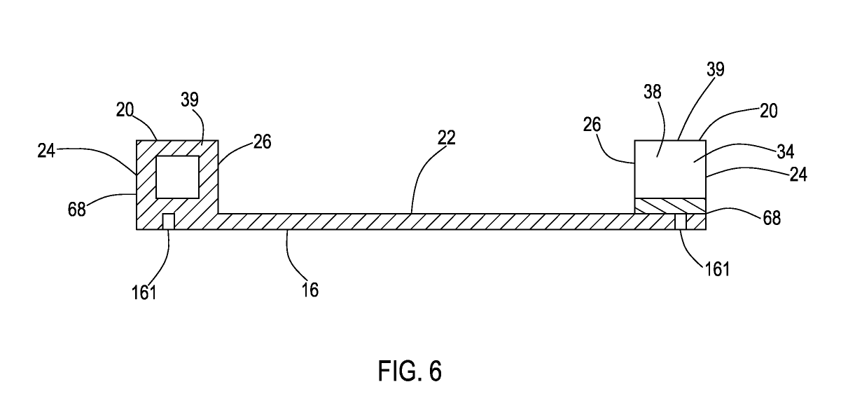

FIG. 6 depicts a cross-sectional view of exemplary protective covering 10′ shown in FIG. 3 as viewed along line B-B. FIG. 6 provides a view of some of the above-described components and features of exemplary housing component 11. Components and features shown in FIG. 6 include, but are not limited to, inner housing front surface 22; rear housing surface 16; opening or recessed area 34 and opening or recessed area surface 38 within housing side wall 20; and recessed groove 161.

Exemplary housing components 10 and 10′ shown in FIGS. 1-4 further comprise semi-circular outcroppings 41 along opposite side edges 42 and 43 of outer peripheral edge 68 of housing components 10 and 10′. Semi-circular outcroppings 41 provide “non-slip stops” so that a user (not shown) can grip housing component 10 or 10′ with both hands along opposite side edges 42 and 43, and the “non-slip stops” in the form of semi-circular outcroppings 41 prevent housing component 10 or 10′ from slipping downward (i.e., semi-circular outcroppings 41 grip the user's index fingers near the main hand knuckle, while allowing the user to easily use his/her thumb(s) to touch, for example, an iPad™ screen near the bottom to make computer inputs while preventing the device from slipping in the user's grip).

As shown in FIG. 4, below semi-circular outcroppings 41, exemplary housing component 10′ may further comprise recessed edge areas 51 along opposite side edges 42 and 43 of outer peripheral edge 68, wherein recessed edge area 51 contacts recessed groove 161 (i.e., recessed edge areas 51 may intersect with recessed groove 161 such that a portion of fold-out prop member 12 (e.g., a outer side surface of fold-out prop member 12), when in a first position, extends into recessed edge areas 51). Recessed edge area 51 allow a user (not shown) to access fold-out prop member 12 near moveable fold-out prop member end 48 to initiate moving fold-out prop member 12 out of recessed groove 161.

Although not shown in the figures, it should be understood that the housing components of the present invention (e.g., exemplary housing components 10 and 10′) may comprise one or more additional features. Suitable additional features may include, but are not limited to, a battery housing compartment, for example, within housing component member 36 and/or 37 on opposite sides of gripping aperture 32 of housing component 10′; batteries; a small amplifier positioned, for example, within housing component member 36 and/or 37 on opposite sides of gripping aperture 32 of housing component 10′; one or more speakers, desirably, two speakers positioned under speaker outlet(s) 35 positioned along outer housing front surface 23, such as shown in FIG. 3; an electrical cord (i.e., connected to one or more electronic components of the housing component) with a plug that can plug into an iPad™'s headphone jack; and other electronic components.

The present invention is also directed to methods of making protective coverings. In one exemplary embodiment of the present invention, the method of making a protective covering comprises the step of forming at least one molded part comprising (i) the housing component, and (ii) the fold-out prop member; and connecting (i) the housing component and (ii) the fold-out prop member to one another. The method of making a protective covering may further comprise one or more additional steps including, but not limited to, printing and/or adhering an image onto an outer surface of the at least one molded part; and packaging the protective covering.

Typically, each of the components of the protective coverings of the present invention is formed via one or more thermoforming steps (e.g., one or more injection molding step). Each of the components of the protective coverings may be formed from any desired material. Typically, each of the components of the protective coverings comprises a thermoformable material such as a polymeric material. Suitable polymeric materials for forming each of the components of the protective coverings include, but are not limited to, a polyolefin (e.g., polyethylene, polypropylene, copolymers of ethylene and propylene), a polyester (e.g., PET), polyvinyl chloride, a polyacrylate (e.g., polymethyl methacrylate), or any other thermoformable polymer. Although polymeric material is typically used to form each of the components of the protective coverings, other suitable materials for forming each of the components of the protective coverings include, but are not limited to, a metallic material (e.g., aluminum), a cellulosic material (e.g., wood), and a ceramic material.

The present invention is even further directed to methods of using the above-described protective coverings to protect and house an electronic device. In one exemplary embodiment of the present invention, the method of using a protective covering comprises a method of covering an electronic device, wherein the method comprises positioning and securing the electronic device along an inner housing surface of the housing component.

In another exemplary embodiment, the method of using a protective covering comprises withdrawing a fold-out prop member from a first position adjacent a lower surface of the housing component; and adjusting a height of the electronic device by adjusting a position of the fold-out prop member relative to the housing component.

The present invention is described above and further illustrated below by way of examples, which are not to be construed in any way as imposing limitations upon the scope of the invention. On the contrary, it is to be clearly understood that resort may be had to various other embodiments, modifications, and equivalents thereof which, after reading the description herein, may suggest themselves to those skilled in the art without departing from the spirit of the present invention and/or the scope of the appended claims.

### EXAMPLE 1

### Preparation of a Protective Covering

Exemplary protective coverings as shown in FIGS. 1-6 were prepared using conventional steps (e.g., one or more thermoforming steps, and one or more connection steps).

It should be understood that although the above-described protective coverings and methods are described as “comprising” one or more components or steps, the above-described protective coverings and methods may “comprise,” “consists of,” or “consist essentially of” any of the above-described components, features or steps of the protective coverings and methods. Consequently, where the present invention, or a portion thereof, has been described with an open-ended term such as “comprising,” it should be readily understood that (unless otherwise stated) the description of the present invention, or the portion thereof, should also be interpreted to describe the present invention, or a portion thereof, using the terms “consisting essentially of” or “consisting of” or variations thereof as discussed below.

As used herein, the terms “comprises,” “comprising,” “includes,” “including,” “has,” “having,” “contains”, “containing,” “characterized by” or any other variation thereof, are intended to encompass a non-exclusive inclusion, subject to any limitation explicitly indicated otherwise, of the recited components. For example, a protective covering and/or method that “comprises” a list of elements (e.g., components, features or steps) is not necessarily limited to only those elements (or components or steps), but may include other elements (or components or steps) not expressly listed or inherent to the protective covering and/or method.

As used herein, the transitional phrases “consists of” and “consisting of” exclude any element, step, or component not specified. For example, “consists of” or “consisting of” used in a claim would limit the claim to the components, materials or steps specifically recited in the claim except for impurities ordinarily associated therewith (i.e., impurities within a given component). When the phrase “consists of” or “consisting of” appears in a clause of the body of a claim, rather than immediately following the preamble, the phrase “consists of” or “consisting of” limits only the elements (or components or steps) set forth in that clause; other elements (or components) are not excluded from the claim as a whole.

As used herein, the transitional phrases “consists essentially of” and “consisting essentially of” are used to define a protective covering and/or method that includes materials, steps, features, components, or elements, in addition to those literally disclosed, provided that these additional materials, steps, features, components, or elements do not materially affect the basic and novel characteristic(s) of the claimed invention. The term “consisting essentially of” occupies a middle ground between “comprising” and “consisting of”.

Further, it should be understood that the herein-described protective coverings and methods may comprise, consist essentially of, or consist of any of the herein-described components and features, as shown in the figures with or without any feature(s) not shown in the figures. In other words, in some embodiments, the protective coverings and/or methods of the present invention do not have any additional features other than those shown in the figures, and such additional features, not shown in the figures, are specifically excluded from the protective coverings and/or methods. In other embodiments, the protective coverings and/or methods of the present invention do have one or more additional features that are not shown in the figures.

While the specification has been described in detail with respect to specific embodiments thereof, it will be appreciated that those skilled in the art, upon attaining an understanding of the foregoing, may readily conceive of alterations to, variations of, and equivalents to these embodiments. Accordingly, the scope of the present invention should be assessed as that of the appended claims and any equivalents thereto.

Further, it should be understood that the present invention may be suitably practiced in the absence of any element/component/feature not specifically disclosed herein.

What is claimed is:

1. A protective covering for protecting and housing an electronic device, said protective covering comprising:
a housing component comprising:
an inner housing front surface;
at least one housing side wall extending upward from said inner housing front surface and comprising an outer housing side wall surface, an inner housing side wall surface opposite said outer housing side wall surface, and an upper side wall surface between said inner housing side wall surface and said outer housing side wall surface;
at least one housing connection member along said inner housing side wall surface and extending over said inner housing front surface;
an outer housing front surface;
an intermediate housing side wall extending upward from said inner housing front surface and separating said inner housing front surface from said outer housing front surface;
a rear housing surface opposite said inner housing front surface and said outer housing front surface; and
an outer peripheral edge extending completely around said housing component;
said inner housing front surface and said at least one housing side wall being sized and dimensioned so as to (i) receive and surround an electronic device positionable along said inner housing front surface, and (ii) secure the electronic device within said protective covering via said at least one housing connection member.

2. The protective covering of claim 1, said housing component further comprising:
a gripping aperture extending through said housing component from said outer housing front surface to said rear housing surface, said gripping aperture being sized and dimensioned so as to enable a user to grab said protective covering by extending at least a portion of a hand through said gripping aperture.

3. The protective covering of claim 1, said housing component further comprising:
one or more air vent apertures extending through said housing component from said inner housing front surface to said rear housing surface, said one or more air vent apertures being sized and dimensioned so as to provide unobstructed air flow from an electronic device positioned along said inner housing front surface.

4. The protective covering of claim 1, further comprising:
a fold-out prop member comprising a connected fold-out prop member end, and a moveable fold-out prop member end opposite said connected fold-out prop member end, said connected fold-out prop member end being connected to said rear housing surface so that said moveable fold-out prop member end is operatively adapted to move from a first parallel position, wherein said moveable fold-out prop member end extends along and is proximate to said rear housing surface, to a second angled position, wherein said moveable fold-out prop member end is positioned away from said rear housing surface.

5. The protective covering of claim 4, wherein said housing component further comprises a recessed groove extending along said rear housing surface, and said fold-out prop member is sized so as to fit within said recessed groove when said fold-out prop member is in the first parallel position.

6. The protective covering of claim 5, wherein said recessed groove extends within at least a portion of said at least one housing side wall.

7. The protective covering of claim 6, wherein said housing component has a rectangular shape, said at least one housing side wall extends along at least three sides of the rectangular shape, and said recessed groove extends within said at least one housing side wall along the at least three sides of the rectangular shape.

8. The protective covering of claim 4, wherein said fold-out prop member is operatively adapted to remain in said first parallel position or said second angled position unless a threshold amount of force is applied to said fold-out prop member.

9. The protective covering of claim 1, wherein said housing component further comprises at least one opening or recessed area within said at least one housing side wall and extending from said outer housing side wall surface to said inner housing front surface, said at least one opening or recessed area being sized to enable one or more electrical cords, cables, or both to connect to an electronic device positioned along said inner housing front surface of said housing component.

10. The protective covering of claim 1, wherein said housing component has a rectangular shape, said at least one housing side wall and said intermediate housing side wall together represent four housing side walls, and each of three of said four housing side walls independently comprise at least one opening or recessed area therein, each of said at least one opening or recessed area being sized to enable one or more electrical cords, cables, or both to connect to an electronic device positioned along said inner housing front surface of said housing component.

11. The protective covering of claim 1, wherein said housing component further comprises at least one speaker outlet positioned along said outer housing front surface, each speaker outlet being sized and dimensioned to match a speaker front surface of a speaker positionable within said housing component.

12. The protective covering of claim 2, wherein said housing component further comprises two speaker outlets positioned along said outer housing front surface on opposite sides of said gripping aperture, each speaker outlet being sized and dimensioned to match a speaker front surface of a speaker positionable within said housing component.

13. The protective covering of claim 1 in combination with an electronic device, said protective covering and said electronic device being sized so that said electronic device can be positioned and secured along said inner housing front surface of said housing component.

14. A protective covering for protecting and housing an electronic device, said protective covering comprising:
(I) a housing component comprising:
an inner housing front surface;
at least one housing side wall extending upward from said inner housing front surface and comprising an outer housing side wall surface, an inner housing side wall surface opposite said outer housing side wall surface, and an upper side wall surface between said inner housing side wall surface and said outer housing side wall surface;
at least one housing connection member along said inner housing side wall surface and extending over said inner housing front surface;
an outer housing front surface;
an intermediate housing side wall extending upward from said inner housing front surface and separating said inner housing front surface from said outer housing front surface;
a rear housing surface opposite said inner housing front surface and said outer housing front surface; and
an outer peripheral edge extending completely around said housing component;
said inner housing front surface and said at least one housing side wall being sized and dimensioned so as to (i) receive and surround an electronic device positionable along said inner housing front surface, and (ii) secure the electronic device within said protective covering via said at least one housing connection member; and
(II) a fold-out prop member comprising a connected fold-out prop member end, and a moveable fold-out prop member end opposite said connected fold-out prop member end, said connected fold-out prop member end being connected to said rear housing surface so that said moveable fold-out prop member end is operatively adapted to move from a first parallel position, wherein said moveable fold-out prop member end extends along and is proximate to said rear housing surface, to a second angled position, wherein said moveable fold-out prop member end is positioned away from said rear housing surface;
wherein said housing component further comprises a recessed groove extending along said rear housing surface, and said fold-out prop member is sized so as to fit within said recessed groove when said fold-out prop member is in the first parallel position.

15. The protective covering of claim 14, wherein said housing component further comprises:
a gripping aperture extending through said housing component from said outer housing front surface to said rear housing surface, said gripping aperture being sized and dimensioned so as to enable a user to grab said protective covering by extending at least a portion of a hand through said gripping aperture;
one or more air vent apertures extending through said housing component from said inner housing front surface to said rear housing surface, said one or more air vent apertures being sized and dimensioned so as to provide unobstructed air flow from an electronic device positioned along said inner housing front surface; and
at least one opening or recessed area within said at least one housing side wall and extending from said outer housing side wall surface to said inner housing front surface, said at least one opening or recessed area being sized to enable one or more electrical cords, cables, or both to connect to an electronic device positioned along said inner housing front surface of said housing component.

16. The protective covering of claim 14, wherein said housing component has a rectangular shape, said at least one housing side wall and said intermediate housing side wall together represent four housing side walls, and each of three of said four housing side walls independently comprise at least one opening or recessed area therein, each of said at least one opening or recessed area being sized to enable one or more electrical cords, cables, or both to connect to an electronic device positioned along said inner housing front surface of said housing component.

17. The protective covering of claim 14 in combination with an electronic device, said protective covering and said electronic device being sized so that said electronic device can be positioned and secured along said inner housing front surface of said housing component.

18. A protective covering for protecting and housing an electronic device, said protective covering comprising:
(I) a housing component comprising:
an inner housing front surface;
at least one housing side wall extending upward from said inner housing front surface and comprising an outer housing side wall surface, an inner housing side wall surface opposite said outer housing side wall surface, and an upper side wall surface between said inner housing side wall surface and said outer housing side wall surface;
at least one housing connection member along said inner housing side wall surface and extending over said inner housing front surface;
an outer housing front surface;
an intermediate housing side wall extending upward from said inner housing front surface and separating said inner housing front surface from said outer housing front surface;
a rear housing surface opposite said inner housing front surface and said outer housing front surface;
an outer peripheral edge extending completely around said housing component;
a gripping aperture extending through said housing component from said outer housing front surface to said rear housing surface, said gripping aperture being sized and dimensioned so as to enable a user to grab said protective covering by extending at least a portion of a hand through said gripping aperture;
one or more air vent apertures extending through said housing component from said inner housing front surface to said rear housing surface, said one or more air vent apertures being sized and dimensioned so as to provide unobstructed air flow from an electronic device positioned along said inner housing front surface;
a recessed groove extending along said rear housing surface; and
a rectangular shape;
wherein said at least one housing side wall and said intermediate housing side wall together represent four housing side walls, and each of three of said four housing side walls independently comprises at least one opening or recessed area therein, each of said at least one opening or recessed area (i) extending from said outer housing side wall surface to said inner housing front surface, and being sized to enable one or more electrical cords, cables, or both to connect to an electronic device positioned along said inner housing front surface of said housing component;
said inner housing front surface and said at least one housing side wall being sized and dimensioned so as to (i) receive and surround an electronic device positionable along said inner housing front surface, and (ii) secure the electronic device within said protective covering via said at least one housing connection member; and
(II) a fold-out prop member comprising a connected fold-out prop member end, and a moveable fold-out prop member end opposite said connected fold-out prop member end, said connected fold-out prop member end being connected to said rear housing surface so that said moveable fold-out prop member end is operatively adapted to move from a first parallel position, wherein said moveable fold-out prop member end extends along and is proximate to said rear housing surface and positioned within said recessed groove, to a second angled position, wherein said moveable fold-out prop member end is positioned away from said rear housing surface.

19. The protective covering of claim 18, wherein said housing component further comprises two speaker outlets positioned along said outer housing front surface on opposite sides of said gripping aperture, each speaker outlet being sized and dimensioned to match a speaker front surface of a speaker positionable within said housing component.

20. The protective covering of claim 19 in combination with an electronic device, said protective covering and said electronic device being sized so that said electronic device can be positioned and secured along said inner housing front surface of said housing component.
